(19) United States
(12) Patent Application Publication
(10) Pub. No.: US 2026/0246445 A1
(43) Pub. Date: Aug. 20, 2026

(54) ACOUSTIC RESONATOR AND MANUFACTURING METHOD THEREFOR

(71) Applicant: University Of Science And Technology Of China, Hefei (CN)

(72) Inventors: Chengjie ZUO, Hefei (CN); Kai YANG, Hefei (CN); Fuhong LIN, Hefei (CN)

(21) Appl. No.: 19/472,087

(22) PCT Filed: Apr. 4, 2023
(86) PCT No.: PCT/CN2023/086200

§ 371 Date: Jan. 12, 2026

(51) Int. Cl. H03H 9/05; H03H 3/02; H03H 9/02; H03H 9/13; H03H 9/17

(52) U.S. Cl. CPC H03H 9/0595; H03H 3/02; H03H 9/02102; H03H 9/02228; H03H 9/132; H03H 9/173; H03H 9/176; H03H 2003/021

(57) ABSTRACT

An acoustic wave resonator is provided, including: a substrate, a released part of which forms a cavity; a piezoelectric layer, including a first portion on the cavity and a second portion on an unreleased part of the substrate, configured to excite acoustic wave under action of a lateral electric field; a support anchor unit disposed between first and second portions of the piezoelectric layer and configured to connect the first and second portions; and a metal electrode layer on the piezoelectric layer, including a metal electrode array formed by at least one pair of positive and negative metal electrodes alternately arranged, the metal electrode array forms the lateral electric field. The support anchor unit includes at least one pair of support anchors respectively disposed on two sides of the first portion of the piezoelectric layer along an extending direction of the metal electrodes.

### TECHNICAL FIELD

At least one embodiment of the present disclosure relates to an acoustic wave resonator, and more particularly to an acoustic wave resonator and a method for manufacturing the same.

### BACKGROUND

As one of the key modules in a radio frequency front end, the performance of a radio frequency filter directly determines the ability of a communication system to extract signals from noises. With the popularization of smartphones, the electromagnetic spectrums below 6 GHz have been fully allocated, and the continuously developing wireless communication industry is shifting toward higher frequency bands and broader bandwidths so as to achieve faster data transmission rates. Recently, the FCC has opened the 12.7~13.25 GHz frequency bands for mobile broadband and other extended applications; and more high-frequency bands are being explored to meet the increasing demands. Mobile RF (radio frequency) front-ends above 10 GHz may outperform their counterparts below 6 GHz, making them a potential solution for 5G wireless communications. To take full advantage of higher frequency spectrums, it is necessary to develop acoustic wave resonators that operate in higher frequency bands.

A resonant frequency of an acoustic wave resonator is primarily determined by a thickness of a piezoelectric thin film. To satisfy the demands of the wireless communication industry for higher frequency bands, the thickness of the piezoelectric thin film needs to be continuously reduced. For applications in the 5G FR2 and higher 6G frequency bands, two common methods are currently used. One method is to use higher-order modes of Lamb wave resonators, which have a higher acoustic velocity and may operate at a higher frequency. However, as the modal increases, an electromechanical coupling coefficient of the acoustic wave resonator decreases sharply, which is not conducive to meeting the bandwidth requirements of high-frequency bands. The other method is to reduce the thickness of the piezoelectric thin film to nanometer level, but a crystallinity of a directly grown piezoelectric thin film at the nanometer level is difficult to meet the application requirements. Currently, a common method is to form a piezoelectric thin film at the nanometer level by transferring the piezoelectric thin film after ion implantation (smart-cut process). However, this method suffers from two problems, one problem is that it is difficult to control a uniformity of the directly transferred piezoelectric thin film at the nanometer level, and the other problem is that the piezoelectric thin film at the nanometer level is prone to fracture during release of a buffer layer.

### SUMMARY

In view of this, an acoustic wave resonator and a method for manufacturing the same are provided, a support anchor structure is formed between a first portion and a second portion of a piezoelectric layer to prevent deformation of the piezoelectric layer during release of the substrate, so as to achieve a high quality factor under a condition of ultra-high resonant frequency.

An acoustic wave resonator is provided, including: a substrate, a part of the substrate is released to form a cavity; a piezoelectric layer including a first portion disposed on the cavity and a second portion disposed on an unreleased part of the substrate, the piezoelectric layer is configured to excite an acoustic wave under an action of a lateral electric field; a support anchor unit disposed between the first portion of the piezoelectric layer and the second portion of the piezoelectric layer, the support anchor unit is configured to connect the first portion and the second portion; and a metal electrode layer formed on the piezoelectric layer, the metal electrode layer includes a metal electrode array formed by alternately arranging at least one pair of positive and negative metal electrodes, and the metal electrode array forms the lateral electric field. The support anchor unit includes at least one pair of support anchors respectively disposed on two sides of the first portion of the piezoelectric layer along an extending direction of a metal electrode of the at least one pair of metal electrodes

A method for manufacturing an acoustic wave resonator is further provided, suitable for manufacturing the acoustic wave resonator described above, the method including: forming the piezoelectric thin film on the substrate; forming the metal electrode layer on the piezoelectric thin film; forming a mask layer on the metal electrode layer, and patterning the mask layer to obtain a patterned mask layer; etching the piezoelectric thin film using the patterned mask layer to obtain the piezoelectric layer and the support anchors, the piezoelectric layer includes the first portion and the second portion; releasing the substrate using a dry release method or a wet release method to form a cavity between the substrate and the piezoelectric layer; and removing the patterned mask layer using a buffered oxide etchant. The support anchors are formed between the first portion and the second portion to suppress deformation of the piezoelectric layer during release of the substrate.

According to the acoustic wave resonator provided in the above embodiments of the present disclosure, because a residual stress exists between the substrate and the piezoelectric layer, the residual stress may cause deformation of the piezoelectric layer during the process of releasing the substrate located beneath the piezoelectric layer. By adding the support anchor structure, the stress between the substrate and the piezoelectric layer is reduced, which may prevent deformation of the piezoelectric layer during release of the substrate, thereby preventing fracture of the piezoelectric layer caused by the stress and improving a stability of the acoustic wave resonator.

According to the acoustic wave resonator provided in the above embodiments of the present disclosure, the support anchors are disposed between the first portion and the second portion of the piezoelectric layer along the extending direction of the metal electrodes to form a pseudo-free boundary at an edge of the first portion of the piezoelectric layer. This reduces leakage of acoustic waves from the first portion of the piezoelectric layer toward the second portion of the piezoelectric layer in an acoustic wave propagation direction, thereby reducing a loss of the acoustic waves, and improving an electromechanical coupling coefficient and quality factor of the acoustic wave resonator.

### BRIEF DESCRIPTION OF THE DRAWINGS

FIG. 1 shows a schematic three-dimensional view of an acoustic wave resonator according to an embodiment of the present disclosure;

FIG. 2 shows a schematic three-dimensional view of an acoustic wave resonator according to another embodiment of the present disclosure;

FIG. 3 shows a schematic three-dimensional view of an acoustic wave resonator according to yet another embodiment of the present disclosure;

FIG. 4 shows a schematic three-dimensional view of an acoustic wave resonator according to yet another embodiment of the present disclosure;

FIG. 5 shows a schematic three-dimensional view of an acoustic wave resonator according to yet another embodiment of the present disclosure;

FIG. 6 shows a schematic three-dimensional view of an acoustic wave resonator according to yet another embodiment of the present disclosure;

FIG. 7 shows a schematic top view of an acoustic wave resonator according to yet another embodiment of the present disclosure;

FIG. 8 shows a schematic cross-sectional view of an acoustic wave resonator according to yet another embodiment of the present disclosure taken along line A-A′ in FIG. 7;

FIG. 9 shows a schematic cross-sectional view of an acoustic wave resonator according to yet another embodiment of the present disclosure taken along line B-B′ in FIG. 7;

FIG. 10 shows a schematic flowchart of a method for manufacturing an acoustic wave resonator according to an embodiment of the present disclosure;

FIG. 11A to FIG. 11E show schematic diagrams of a manufacturing process of an acoustic wave resonator according to an embodiment of the present disclosure;

FIG. 12 shows a schematic cross-sectional view of an acoustic wave resonator according to yet another embodiment of the present disclosure taken along line A-A′ in FIG. 7;

FIG. 13 shows a schematic cross-sectional view of an acoustic wave resonator according to yet another embodiment of the present disclosure taken along line B-B′ in FIG. 7;

FIG. 14 shows a schematic cross-sectional view of an acoustic wave resonator according to yet another embodiment of the present disclosure taken along line A-A′ in FIG. 7;

FIG. 15 shows a schematic cross-sectional view of an acoustic wave resonator according to yet another embodiment of the present disclosure taken along line B-B′ in FIG. 7; and

FIG. 16 shows a comparison diagram of simulated performance between an acoustic wave resonator of Embodiment 1 of the present disclosure and an acoustic wave resonator of Comparative Example 1.

### DESCRIPTION OF REFERENCE NUMERALS

1—Substrate;
   11—Support substrate;
   12—Rich well layer;
   13—Release layer;
2—Piezoelectric thin film;
3—Metal electrode layer;
4—Patterned mask layer;
5—Piezoelectric layer;
6—Support anchor;
7—Temperature compensation layer;
d₁—Width of support anchor;
d₂—Length of support anchor;
d₃—Width of metal electrode.

### DETAILED DESCRIPTION OF EMBODIMENTS

To make the objectives, technical solutions, and advantages of the present disclosure clearer, the present disclosure will be further described in detail below with reference to specific embodiments and the accompanying drawings. However, the present disclosure may be implemented in different forms and should not be construed as being limited to the embodiments set forth here. On the contrary, these embodiments are provided to make the present disclosure thorough and complete, and to fully convey the scope of the present disclosure to those skilled in the art. In the accompanying drawings, the sizes and relative sizes of layers and regions may be exaggerated for clarity, and the same reference numerals indicate the same elements throughout the accompanying drawings.

The terms used here are intended only to describe the specific embodiments and are not intended to limit the present disclosure. As used here, the terms “including”, “comprising” and similar expressions indicate the presence of stated features, steps, operations, and/or components, but do not exclude the presence or addition of one or more other features, steps, operations, or components.

In view of this, to overcome a stress between a substrate and a piezoelectric layer, prevent deformation of the piezoelectric layer during release of the substrate and improve a stability of an acoustic wave resonator, the present disclosure provides an acoustic wave resonator and a method for manufacturing the same.

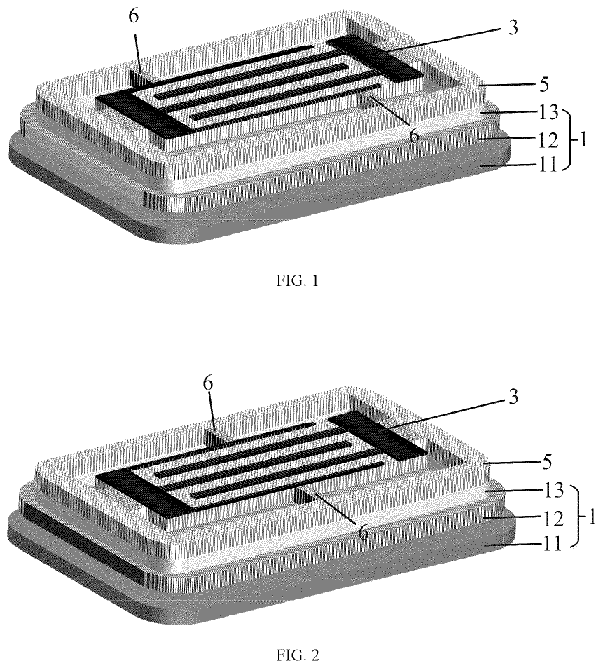

FIG. 1 shows a schematic three-dimensional view of an acoustic wave resonator according to an embodiment of the present disclosure.

According to an exemplary embodiment of the present disclosure, an acoustic wave resonator is provided. Referring to FIG. 1, the acoustic wave resonator includes: a substrate 1, where a part of the substrate 1 is released to form a cavity; a piezoelectric layer 5, including a first portion disposed on the cavity and a second portion disposed on an unreleased part of the substrate 1, where the piezoelectric layer 5 is configured to excite an acoustic wave under an action of a lateral electric field; a support anchor unit disposed between the first portion of the piezoelectric layer 5 and the second portion of the piezoelectric layer 5 and configured to connect the first portion and the second portion; and a metal electrode layer 3 formed on the piezoelectric layer 5, where the metal electrode layer 3 includes a metal electrode array formed by at least one pair of positive and negative metal electrodes arranged alternately, and the metal electrode array forms the lateral electric field. The support anchor unit includes at least one pair of support anchors 6 respectively disposed on two sides of the first portion of the piezoelectric layer 5 along an extending direction of a metal electrode of the at least one pair of metal electrodes.

According to the embodiments of the present disclosure, the support anchor is disposed between the first portion and the second portion of the piezoelectric layer along the extending direction of the metal electrode to form a pseudo-free boundary at an edge of the first portion of the piezoelectric layer, thereby reducing leakage of an acoustic wave from the first portion of the piezoelectric layer toward the second portion of the piezoelectric layer in an acoustic wave propagation direction, reducing a loss of the acoustic wave, and improving an electromechanical coupling coefficient and a quality factor of the acoustic wave resonator.

According to the embodiments of the present disclosure, referring to FIG. 1, the support anchor unit includes a pair of support anchors 6 that are asymmetrically arranged on two sides of the first portion of the piezoelectric layer 5 along the extending direction of the metal electrode.

FIG. 2 shows a schematic three-dimensional view of an acoustic wave resonator according to another embodiment of the present disclosure.

According to the embodiments of the present disclosure, referring to FIG. 2, the support anchor unit includes a pair of support anchors 6 that are symmetrically arranged on two sides of the first portion of the piezoelectric layer 5 along the extending direction of the metal electrode.

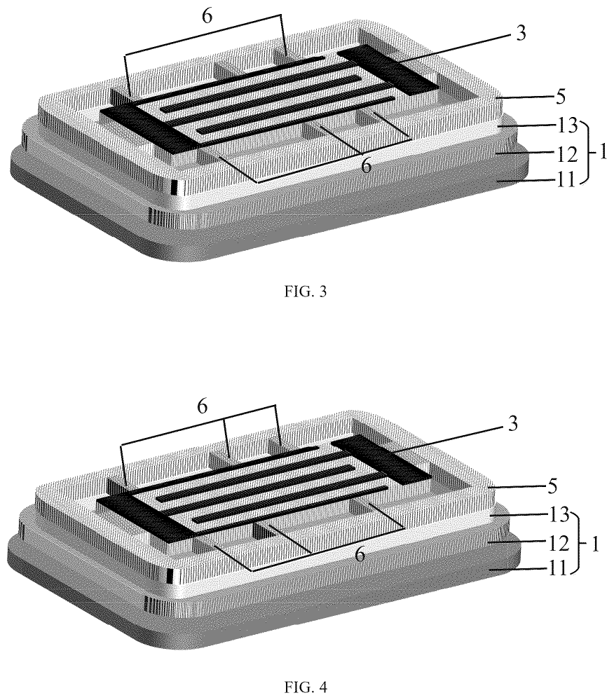

FIG. 3 shows a schematic three-dimensional view of an acoustic wave resonator according to yet another embodiment of the present disclosure.

According to the embodiments of the present disclosure, referring to FIG. 3, the support anchor unit includes a plurality of pairs of support anchors 6 that are symmetrically arranged on two sides of the first portion of the piezoelectric layer 5 along the extending direction of the metal electrode.

FIG. 4 shows a schematic three-dimensional view of an acoustic wave resonator according to yet another embodiment of the present disclosure.

According to the embodiments of the present disclosure, referring to FIG. 4, the support anchor unit includes a plurality of pairs of support anchors 6 that are asymmetrically arranged on two sides of the first portion of the piezoelectric layer 5 along the extending direction of the metal electrode.

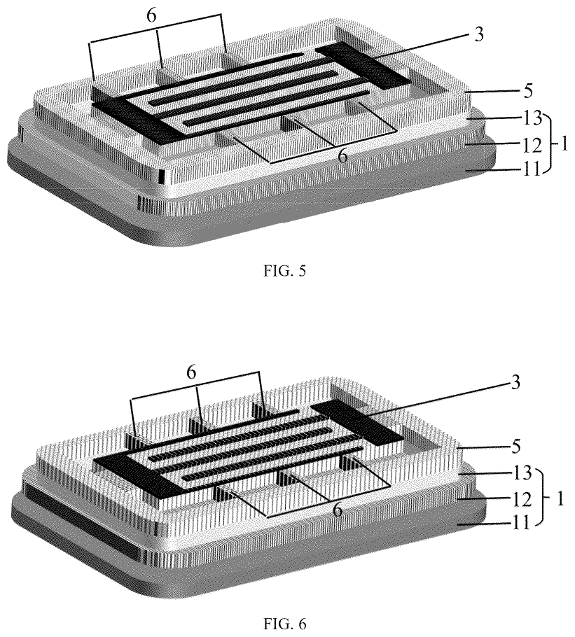

FIG. 5 shows a schematic three-dimensional view of an acoustic wave resonator according to yet another embodiment of the present disclosure.

According to the embodiments of the present disclosure, referring to FIG. 5, the support anchor unit includes a plurality of pairs of support anchors 6 that are asymmetrically arranged on two sides of the first portion of the piezoelectric layer 5 along the extending direction of the metal electrode. Moreover, the support anchors 6 on each side of the first portion of the piezoelectric layer 5 are periodically arranged along the extending direction of the metal electrode.

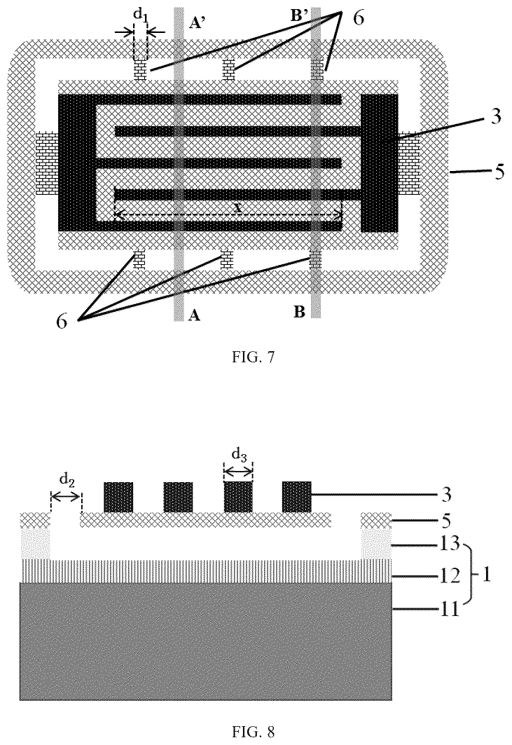

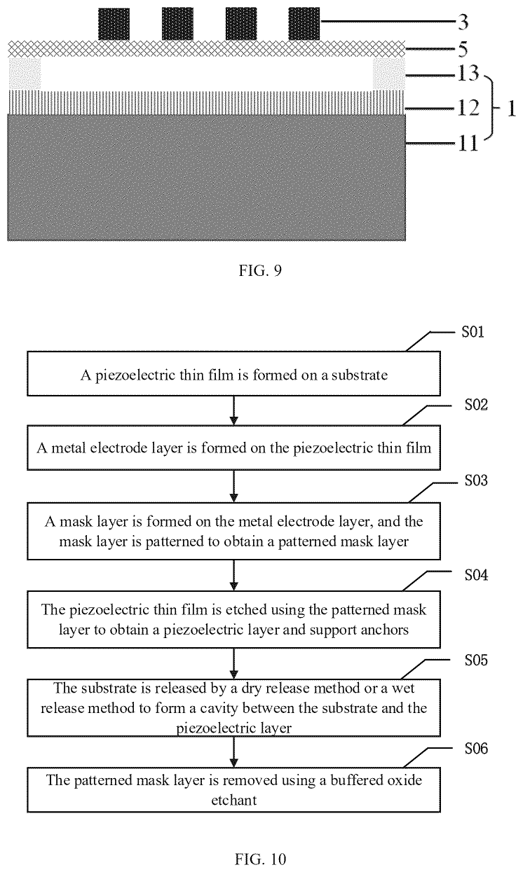

FIG. 6 shows a schematic three-dimensional view of an acoustic wave resonator according to yet another embodiment of the present disclosure. FIG. 7 shows a schematic top view of an acoustic wave resonator according to yet another embodiment of the present disclosure. FIG. 8 shows a schematic cross-sectional view of an acoustic wave resonator according to yet another embodiment of the present disclosure taken along line A-A′ in FIG. 7. FIG. 9 shows a schematic cross-sectional view of an acoustic wave resonator according to yet another embodiment of the present disclosure taken along line B-B′ in FIG. 7.

According to the embodiments of the present disclosure, referring to FIG. 6 to FIG. 7, the support anchor unit includes a plurality of pairs of support anchors 6 that are symmetrically arranged on two sides of the first portion of the piezoelectric layer 5 along the extending direction of the metal electrode. Moreover, the support anchors 6 on each side of the first portion of the piezoelectric layer 5 are periodically arranged along the extending direction of the metal electrode.

According to the embodiments of the present disclosure, referring to FIG. 7 to FIG. 9, a plurality of support anchors 6 are periodically arranged along an aperture direction of the acoustic wave resonator (i.e., the extending direction of the metal electrode, or the x direction). A width d₁ of the support anchor 6 is set to be equal to a width d₃ of the metal electrode, or the width d₁ of the support anchor 6 is a multiple of the width d₃ of the metal electrode, so as to form a pseudo-free boundary at an edge of the first portion of the piezoelectric layer 5. The acoustic wave undergoes total reflection (acoustic impedance mismatch) when propagating to the pseudo-free boundary, so that the acoustic wave is confined within a resonator body, thereby reducing a leakage of the acoustic wave from the first portion of the piezoelectric layer 5 toward the second portion of the piezoelectric layer 5, reducing the loss of the acoustic wave, and improving the electromechanical coupling coefficient and quality factor of the acoustic wave resonator.

According to the embodiments of the present disclosure, a period of the support anchors 6 is set to be equal to a wavelength of the acoustic wave, so as to form the pseudo-free boundary at the edge of the first portion of the piezoelectric layer 5 to reduce the loss of the acoustic wave.

According to the embodiments of the present disclosure, the width d₁ of the support anchor 6 is set to be equal to the width d₃ of the metal electrode, or the width d₁ of the support anchor 6 is a multiple of the width d₃ of the metal electrode, and the period of the support anchors 6 is set to be equal to the wavelength of the acoustic wave, so as to form the pseudo-free boundary at the edge of the first portion of the piezoelectric layer 5 to reduce the loss of the acoustic wave.

According to the embodiments of the present disclosure, the substrate 1 is formed of a high-resistivity material, and a resistivity of the substrate 1 is greater than 1000 Ω/cm³. Using the high-resistivity material as the substrate 1 to form the acoustic wave resonator may reduce a radio frequency loss of the acoustic wave resonator.

According to the embodiments of the present disclosure, the substrate 1 may include a support substrate 11, a rich well layer 12, and a release layer 13 that are sequentially arranged. A material of the support substrate 11 includes at least one selected from silicon, silicon nitride, silicon oxide, silicon carbide, gallium nitride, and gallium oxide. A material of the rich well layer 12 includes, but is not limited to, amorphous silicon or polycrystalline silicon. The release layer 13 includes one or more layers, and a material of each layer includes silicon dioxide, silicon nitride, or silicon. A thickness of the release layer 13 is in a range of 0.1 μm to 100 μm, for example, 0.1 μm, 1 μm, 10 μm, 50 μm, or 100 μm.

According to the embodiments of the present disclosure, a material of the piezoelectric layer 5 includes: lithium niobate; lithium tantalate; a composite layer material composed of lithium niobate and one or more materials selected from aluminum nitride and scandium-doped aluminum nitride; or a composite layer material composed of lithium tantalate and one or more materials selected from aluminum nitride and scandium-doped aluminum nitride.

According to the embodiments of the present disclosure, a thickness of the piezoelectric layer 5 is less than 700 nm, for example, 1 nm, 100 nm, 300 nm, 500 nm, or 700 nm.

It should be noted that, to achieve an acoustic wave resonator with a higher resonant frequency, it is necessary to reduce the thickness of the piezoelectric thin film. As the resonant frequency increases, the thickness of the piezoelectric thin film used in the acoustic wave resonator decreases to the nanometer level. In this case, the stress of the nanometer-sized piezoelectric thin film increases and may cause fracture. By introducing a support anchor structure between the first portion and the second portion of the piezoelectric layer, the stress between the substrate and the piezoelectric layer may be reduced, thereby avoiding deformation of the piezoelectric layer, preventing fracture of the piezoelectric layer caused by stress during release of the substrate, and improving the stability of the acoustic wave resonator.

According to the embodiments of the present disclosure, the metal electrode layer 3 includes at least one pair of metal electrodes arranged in an array. A material of the metal electrodes includes: gold, aluminum, molybdenum, platinum, copper, titanium-gold alloy, titanium-aluminum alloy, titanium-copper alloy, chromium-gold alloy, chromium-aluminum alloy, or chromium-copper alloy. A thickness of the metal electrode is in a range of 1 nm to 100 nm, for example, 1 nm, 10 nm, 20 nm, 50 nm, or 100 nm. The number of the metal electrodes is in a range of 1 to 250 pairs.

According to the embodiments of the present disclosure, the metal electrodes are formed on the support anchors 6, or no metal electrodes are formed on the support anchors 6. When the metal electrodes are formed on the support anchors 6, the metal electrodes on the support anchors 6 may be grounded to an outside to manufacture a single-port device.

According to the embodiments of the present disclosure, the type of the above-described acoustic wave resonator is not limited here. For example, the above-described acoustic wave resonator may be a bulk acoustic wave resonator or a Lamb wave resonator.

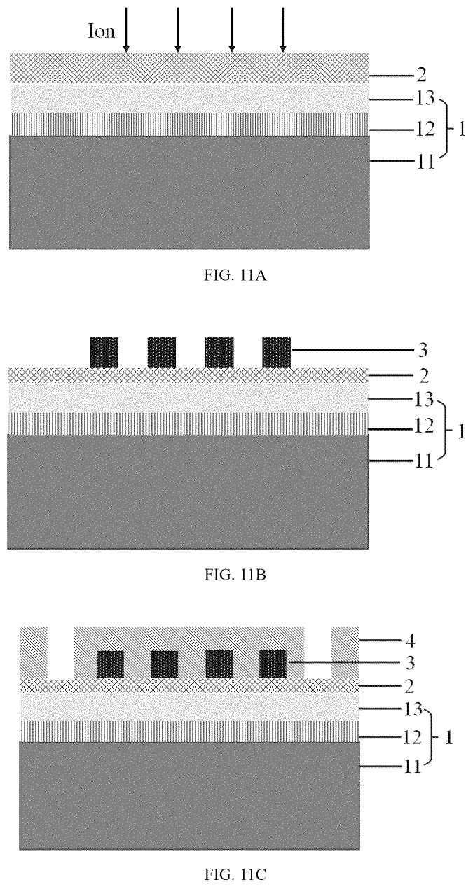

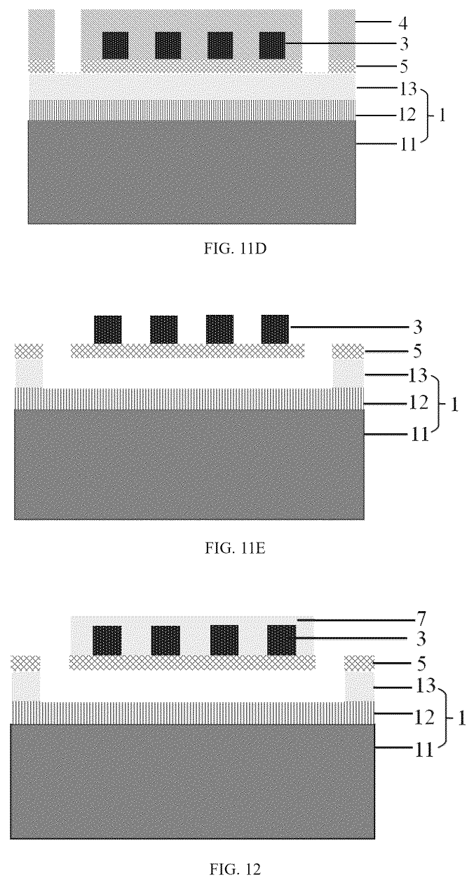

FIG. 10 shows a schematic flowchart of a method for manufacturing an acoustic wave resonator according to an embodiment of the present disclosure. FIG. 11A to FIG. 11E show schematic diagrams of a manufacturing process of an acoustic wave resonator according to an embodiment of the present disclosure.

According to an exemplary embodiment of the present disclosure, a method for manufacturing an acoustic wave resonator is provided, suitable for manufacturing the above-described acoustic wave resonator. Referring to FIG. 10 and FIG. 11A to FIG. 11E, the method includes steps S01 to S06.

In step S01, a piezoelectric thin film 2 is formed on a substrate 1.

According to the embodiments of the present disclosure, the substrate 1 may include a support substrate 11, a rich well layer 12, and a release layer 13 that are sequentially arranged, and the rich well layer 12 and the release layer 13 are sequentially formed on the support substrate 11. The rich well layer 12 may be formed by methods including, but not limited to, ion implantation, sputtering growth, and transfer. The formation of the rich well layer 12 on the support substrate 11 may prevent PSC (parasitic surface conduction) between the support substrate 11 and the release layer 13, thereby reducing a radio frequency loss of the acoustic wave resonator.

According to the embodiments of the present disclosure, the piezoelectric thin film 2 may be formed by any one of ion implantation and transfer, sputtering deposition, molecular beam epitaxy deposition, and vapor phase epitaxy growth and deposition.

In step S02, a metal electrode layer 3 is formed on the piezoelectric thin film 2,

According to the embodiments of the present disclosure, one or more metal layers may be deposited on the piezoelectric thin film 2 by electron beam evaporation or magnetron sputtering, and the metal electrode layer 3 may be formed by a peel-off process.

In step S03, a mask layer is formed on the metal electrode layer 3, and the mask layer is patterned to obtain a patterned mask layer 4.

According to the embodiments of the present disclosure, a material of the mask layer includes at least one selected from: photoresist, silicon oxide, or silicon nitride.

In step S04, the piezoelectric thin film 2 is etched by inductively coupled plasma etching to obtain a piezoelectric layer 5 and a support anchor 6.

In step S05, the substrate 1 is released by a dry release method or a wet release method to form a cavity between the substrate 1 and the piezoelectric layer 5, so as to release a space between the substrate 1 and the piezoelectric layer 5.

According to the embodiments of the present disclosure, the dry release method includes treating the substrate 1 with gases such as HF and XeF₂.

According to the embodiments of the present disclosure, the wet release method includes treating the substrate 1 with a hydrofluoric acid solution, BoE, a potassium hydroxide solution, or a tetramethylammonium hydroxide solution.

According to the embodiments of the present disclosure, referring to FIG. 8, in a case where the substrate 1 includes the support substrate 11, the rich well layer 12, and the release layer 13 that are sequentially arranged, the release layer 13 may be released by a dry release method or by using a hydrofluoric acid solution or BoE to form a cavity between the rich well layer 12 and the piezoelectric layer 5.

In step S06, the patterned mask layer is removed using a buffered oxide etchant.

It should be noted that it is difficult to directly manufacture a piezoelectric thin film with a thickness of less than 700 nm. Therefore, after the piezoelectric thin film 2 is manufactured on the substrate 1, the piezoelectric thin film 2 may be thinned using an ion beam etching method so that the thickness of the piezoelectric thin film 2 is reduced to less than 700 nm, thereby manufacturing an acoustic wave resonator with a higher resonant frequency.

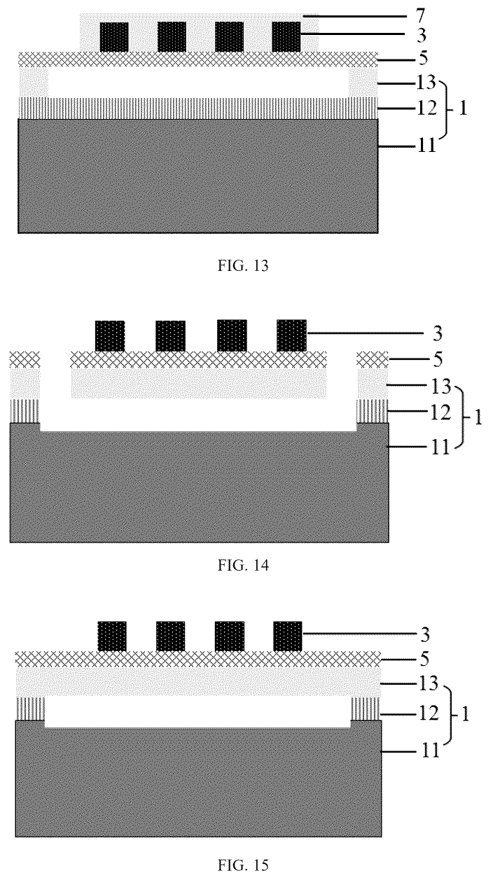

FIG. 12 shows a schematic cross-sectional view of an acoustic wave resonator according to yet another embodiment of the present disclosure taken along line A-A′ in FIG. 7. FIG. 13 shows a schematic cross-sectional view of an acoustic wave resonator according to yet another embodiment of the present disclosure taken along line B-B′ in FIG. 7.

According to the embodiments of the present disclosure, referring to FIG. 12 and FIG. 13, a temperature compensation layer 7 is further formed on the metal electrode layer 3 to provide temperature compensation for the acoustic wave resonator. A material of the temperature compensation layer 7 may include SiO₂.

FIG. 14 shows a schematic cross-sectional view of an acoustic wave resonator according to yet another embodiment of the present disclosure taken along line A-A′ in FIG. 7. FIG. 15 shows a schematic cross-sectional view of an acoustic wave resonator according to yet another embodiment of the present disclosure taken along line B-B′ in FIG. 7.

According to the embodiments of the present disclosure, referring to FIG. 14 and FIG. 15, releasing the substrate 1 using a dry release method or a wet release method to form a cavity between the substrate 1 and the piezoelectric layer 5 includes: the substrate 1 is treated with a potassium hydroxide solution or a tetramethylammonium hydroxide solution to remove the rich well layer 12 and a part of the support substrate 11, thereby forming a cavity between the support substrate 11 and the release layer 13m, the release layer 13 located beneath the piezoelectric layer 5 serves as the temperature compensation layer.

The structure of the designed acoustic wave resonator is illustratively described below. It should be noted that this example is merely a specific embodiment of the present disclosure and does not limit the scope of protection of the present disclosure.

### Embodiment 1

Taking a Lamb wave resonator as an example, a lithium niobate thin film with a thickness of 90 nm is used to form the piezoelectric layer on the substrate having a resistivity greater than 1000 Ω/cm³. The width of the metal electrode is in a range of 1 μm to 10 μm. The support anchors are arranged between the first portion and the second portion of the piezoelectric layer along the extending direction of the metal electrode. The width of the support anchor is equal to the width of the metal electrode, and the period of the support anchors is equal to a distance between two adjacent metal electrodes of a same polarity. A distance between two adjacent metal electrodes of different polarities is in a range of 1 μm to 15 μm, and the thickness of the metal electrode is in a range of 10 nm to 100 nm, so as to manufacture the Lamb wave resonator. The thickness of the piezoelectric layer may be adjusted within the range of 1 nm to 700 nm to achieve a higher resonant frequency and quality factor.

The simulated performance of the manufactured Lamb wave resonator is analyzed using COMSOL finite element analysis software based on a MBVD (Modified Butterworth-Van Dyke) model.

### Comparative Example 1

Taking a Lamb wave resonator as an example, a lithium niobate thin film with a thickness of 90 nm is used to form a piezoelectric layer on a substrate having a resistivity greater than 1000 Ω/cm³, the width of the metal electrode is in a range of 1 μm to 10 μm, and no support anchor is provided between the first portion and the second portion of the piezoelectric layer.

The simulated performance of the manufactured Lamb wave resonator is analyzed using COMSOL finite element analysis software based on a MBVD (Modified Butterworth-Van Dyke) model.

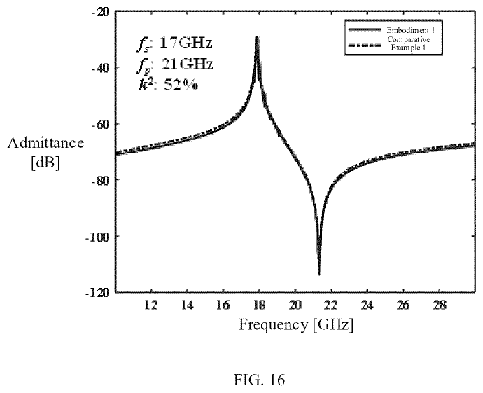

FIG. 16 shows a comparison diagram of the simulated performance between the acoustic wave resonator of Embodiment 1 of the present disclosure and the acoustic wave resonator of Comparative Example 1.

Referring to FIG. 16, the simulated results demonstrate that the acoustic wave resonator manufactured in Embodiment 1 achieves an electromechanical coupling coefficient (k²) greater than 50% in an ultra-high frequency band with a resonant frequency greater than 17 GHz, and a quality factor greater than 1000 as calculated using a 3 dB-Q calculation method, which well meets the performance requirements for high resonant frequency, high broad bandwidth, and high electromechanical coupling coefficient of resonators in current 5G and 6G frequency bands. Moreover, the simulated performance of the acoustic wave resonator of Embodiment 1 is not inferior than the simulated performance of the acoustic wave resonator without the support anchor in Comparative Example 1. Here, fs represents a resonant frequency, and fₚ represents an anti-resonant frequency.

According to the embodiments of the present disclosure, the piezoelectric thin film is thinned to a thickness of less than 700 nm to achieve a high resonant frequency; meanwhile, a high-resistivity substrate is employed to reduce radio frequency loss; in addition, a support anchor structure is added, where the width of the support anchor is set to be equal to or a multiple of the width of the metal electrode, and/or the period of the support anchors is set to be equal to the wavelength of the acoustic wave, so as to form a pseudo-free boundary at the edge of the first portion of the piezoelectric layer to reduce the loss of the acoustic wave. This further achieves a high quality factor (quality factor greater than 1000) under the condition of ultra-high resonant frequency (resonant frequency greater than 10 GHz) to meet the application requirements of 5G/6G high-frequency bands. By providing the support anchors between the first portion and the second portion of the piezoelectric layer, the stability of the acoustic wave resonator is improved without degrading the performance of the acoustic wave resonator.

According to the acoustic wave resonator provided in the above embodiments of the present disclosure, since the residual stress existing between the substrate and the piezoelectric layer may cause deformation of the piezoelectric layer during the process of releasing the substrate located beneath the piezoelectric layer, the support anchor structure is added to reduce the stress between the substrate and the piezoelectric layer, which may prevent deformation of the piezoelectric layer during release of the substrate, thereby preventing fracture of the piezoelectric layer caused by the stress, and improving the stability of the acoustic wave resonator.

According to the acoustic wave resonator provided in the above embodiments of the present disclosure, the support anchors are arranged between the first portion and the second portion of the piezoelectric layer along the extending direction of the metal electrode to form the pseudo-free boundary at the edge of the first portion of the piezoelectric layer, so as to reduce leakage of the acoustic wave from the first portion of the piezoelectric layer toward the second portion of the piezoelectric layer in the acoustic wave propagation direction, reduce the loss of the acoustic wave, and improve the electromechanical coupling coefficient and quality factor of the acoustic wave resonator.

The specific embodiments described above further explain the objectives, technical solutions, and beneficial effects of the present disclosure in detail. It should be understood that the above are merely specific embodiments of the present disclosure and are not intended to limit the present disclosure. Any modifications, equivalent substitutions, improvements, etc., made within the spirit and principles of the present disclosure shall be included in the scope of protection of the present disclosure.

1. An acoustic wave resonator, comprising:
a substrate, wherein a part of the substrate is released to form a cavity;
a piezoelectric layer comprising a first portion disposed on the cavity and a second portion disposed on an unreleased part of the substrate, wherein the piezoelectric layer is configured to excite an acoustic wave under an action of a lateral electric field;
a support anchor unit disposed between the first portion of the piezoelectric layer and the second portion of the piezoelectric layer, wherein the support anchor unit is configured to connect the first portion and the second portion; and
a metal electrode layer formed on the piezoelectric layer, wherein the metal electrode layer comprises a metal electrode array formed by alternately arranging at least one pair of positive and negative metal electrodes, and the metal electrode array forms the lateral electric field,
wherein the support anchor unit comprises at least one pair of support anchors respectively disposed on two sides of the first portion of the piezoelectric layer along an extending direction of a metal electrode of the at least one pair of metal electrodes.

2. The acoustic wave resonator of claim 1, wherein the support anchor unit comprises a plurality of pairs of support anchors symmetrically arranged on two sides of the first portion of the piezoelectric layer along the extending direction of the metal electrode.

3. The acoustic wave resonator of claim 2, wherein the support anchors disposed on each side of the first portion of the piezoelectric layer are periodically arranged along the extending direction of the metal electrode.

4. The acoustic wave resonator of claim 3, wherein,
a width of a support anchor of the support anchors is equal to a width of the metal electrode, or the width of the support anchor is a multiple of the width of the metal electrode; and/or
an arrangement period of the support anchors is equal to a wavelength of the acoustic wave.

5. The acoustic wave resonator of claim 1, wherein the substrate is formed of a high-resistivity material, and a resistivity of the substrate is greater than 1000 Ω/cm³.

6. The acoustic wave resonator of claim 5, wherein,
the substrate comprises a support substrate, a rich well layer, and a release layer that are sequentially arranged;
a material of the support substrate comprises at least one selected from sapphire, silicon, silicon nitride, silicon oxide, silicon carbide, gallium nitride, glass, and gallium oxide;
a material of the rich well layer comprises amorphous silicon or polycrystalline silicon;
the release layer comprises one or more layers, and a material of each layer comprises silicon dioxide, silicon nitride, or silicon; and
a thickness of the release layer is in a range of 0.05 μm to 100 μm.

7. The acoustic wave resonator of claim 1, wherein a material of the piezoelectric layer comprises one of the following:
lithium niobate;
lithium tantalate;
a composite layer material formed of lithium niobate and one or more materials selected from aluminum nitride and scandium-doped aluminum nitride; and
a composite layer material formed of lithium tantalate and one or more materials selected from aluminum nitride and scandium-doped aluminum nitride.

8. The acoustic wave resonator of claim 7, wherein a thickness of the piezoelectric layer is less than 700 nm.

9. The acoustic wave resonator of claim 1, wherein,
a material of the metal electrode comprises one of the following: gold, aluminum, molybdenum, platinum, copper, titanium-gold alloy, titanium-aluminum alloy, titanium-copper alloy, chromium-gold alloy, chromium-aluminum alloy, and chromium-copper alloy;
a thickness of the metal electrode is in a range of 1 nm to 1000 nm; and
a number of the metal electrodes is in a range of 1 to 250 pairs.

10. The acoustic wave resonator of claim 9, wherein,
the metal electrodes are formed on the support anchors; or
no metal electrodes are formed on the support anchors.

11. A method for manufacturing an acoustic wave resonator, suitable for manufacturing the acoustic wave resonator of claim 1, the method comprising:
forming the piezoelectric thin film on the substrate;
forming the metal electrode layer on the piezoelectric thin film;
forming a mask layer on the metal electrode layer, and patterning the mask layer to obtain a patterned mask layer;
etching the piezoelectric thin film using the patterned mask layer to obtain the piezoelectric layer and the support anchors, wherein the piezoelectric layer comprises the first portion and the second portion;
releasing the substrate using a dry release method or a wet release method to form a cavity between the substrate and the piezoelectric layer; and
removing the patterned mask layer using a buffered oxide etchant,
wherein the support anchors are formed between the first portion and the second portion to suppress deformation of the piezoelectric layer during release of the substrate.

12. The method of claim 11, further comprising: after forming the piezoelectric thin film on the substrate, thinning the piezoelectric thin film such that a thickness of the piezoelectric thin film is less than 700 nm.

13. The method of claim 11, wherein,
the substrate comprises a support substrate, a rich well layer, and a release layer that are sequentially arranged; and
the release layer is released using the dry release method or the wet release method to form a cavity between the rich well layer and the piezoelectric layer.
